(19) United States
(12) Patent Application Publication
(10) Pub. No.: US 2015/0311747 A1
(43) Pub. Date: Oct. 29, 2015

(54) MINI SOLAR PORTABLE MULTI-DEVICE

(71) Applicant: Ko-Chien CHU, Taoyuan Hsien (TW)

(72) Inventor: Ko-Chien CHU, Taoyuan Hsien (TW)

(73) Assignee: SPEEDTECH ENERGY CO.,LTD., Taoyuan Hsien (TW)

(21) Appl. No.: 14/260,198

(22) Filed: Apr. 23, 2014

(51) Int. Cl. H02J 7/35; H05K 7/14; H05B 33/08; H02J 1/00

(52) U.S. Cl. CPC H02J 7/355; H02J 1/00; H05K 7/1427; H05B 33/0854

(57) ABSTRACT

A mini solar portable multi-device includes a solar module for converting solar energy and transmitting electric energy to a battery inside the body, a radio control circuit board that has a connector set and an audio changeover switch, and a loudspeaker seat holding a loudspeaker that sounds audio signals or acoustic warnings and a light-emitting member control circuit board that has a light-emitting member, a light-emitting control circuit, a brightness and light-emitting mode touch switch, and a light-detection control circuit for providing consistent illumination or warning flashes. The device performs self-charging under sunlight or gets charged by the grid, and then charge an external cell phone. The front cover has buttons communicated with the radio control circuit board for selecting playing modes, for switching tracks, for adjusting volume, for playing or stopping, and for playing and pausing music and switching between radio stations, respectively.

### BACKGROUND OF THE INVENTION

1. Technical Field

The present invention relates to a mini solar portable multi-device, which is a device capable of charging itself, charging a cell phone, acting as an emergency light source, giving acoustic warning, providing general illumination, acting as a radio and playing music.

2. Description of Related Art

For providing a device that meets the practical needs better, the inventor has paid great effort to do research and development in order to solve the problems related to the use of the conventional devices.

### SUMMARY OF THE INVENTION

The primary objective of the present invention is to provide a mini solar portable multi-device, which integrates the functions of an emergency light source, a flashing beacon, an SOS annunciator and an emergency cell-phone charger. For the illumination function, the light illumination and the flashing beacon are adjusted and activated through touch control. For charging external cell phones, its emergency charger connector has an electric specification of 5V-800 mAh, conforming to charging needs of general cell phones. It uses a high-performance monocrystalline silicon 1.3 W solar module as well as a, lithium-ion battery of 3.7V-2250 mAh. In sunny days, the solar module exposed to sunlight charges the lithium-ion battery inside the body. In cloudy days, it is possible to use an external power source of 5V-500-1000 mAh to charge the solar energy radio. The disclosed device is therefore perfect for use in occasions such as travel, mountain-climbing, fishing, camping, long driving and emergency. It can act as a beacon or an annunciator for protection of individual safety. It is convenient to use and highly portable.

For achieving the foregoing objective, the disclosed device comprises a body. The body has a front cover and a back cover. The back cover covers a monocrystalline silicon solar module, which converts solar energy into electric energy and transmits to a battery in the body for supplying power. The body contains a partition on whose front surface a radio control circuit board and a light-emitting member control circuit board are affixed adjacently. The light-emitting member control circuit board has a ring-like light-emitting member, a light-emitting control circuit, a light-detection control circuit, and a brightness and light-emitting mode touch switch. The light-emitting member comprises a plurality of light-emitting diodes for providing consistent illumination or warning flashes. The radio control circuit board has a USB connector and a mini USB connector, an earphone jack, and an audio changeover switch. In the lower part of the body there are a battery compartment and a loudspeaker seat. The loudspeaker seat holds a loudspeaker that gives out music or acoustic warnings. The device can perform self-charging when exposed in sunlight or otherwise get charged by the grid, and then charge an external cell phone through a charger connector that is located on a lateral of the body and communicated with the radio control circuit board. The front cover has a button set that is communicated with the radio control circuit board, wherein the button set includes buttons for selecting playing modes, for switching tracks or adjusting volume, for playing or stopping, and for playing and pausing music and switching between radio stations, respectively. The front cover has a display screen for displaying the power level, the playing modes, and the number of tracks. The front cover includes a light-penetrable area and a sound-penetrable area. The body has its lateral provided with a power-level indicating lamp and a micro SD card connector.

The invention as well as a preferred mode of use, further objectives and advantages thereof will be best understood by reference to the following detailed description of illustrative embodiments when read in conjunction with the accompanying drawings.

### BRIEF DESCRIPTION OF THE DRAWINGS

FIG. 1 is a perspective view of the present invention.

FIG. 2 is a front exploded view of the present invention.

FIG. 3 is a rear exploded view of the present invention the present invention.

FIG. 4 shows the device of FIG. 2 assembled with the front cover lifted.

### DETAILED DESCRIPTION OF THE INVENTION

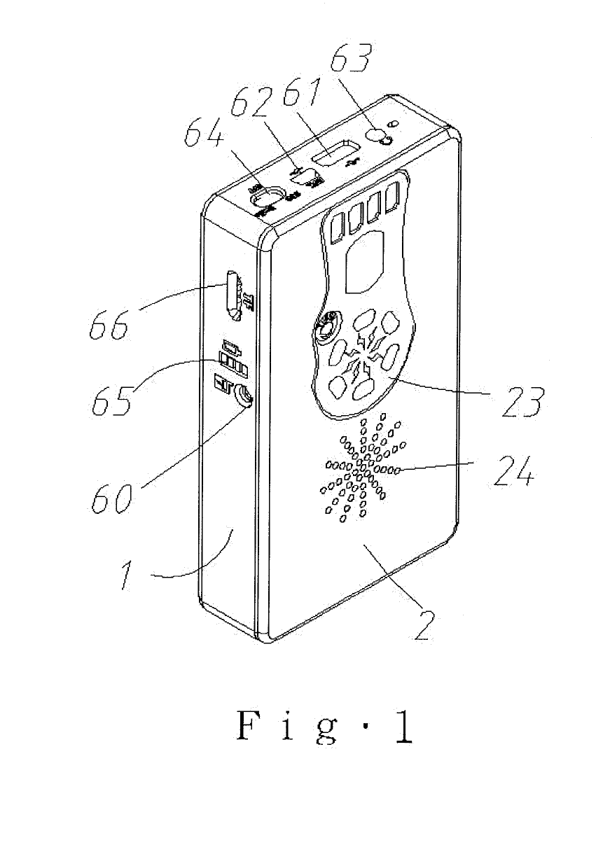

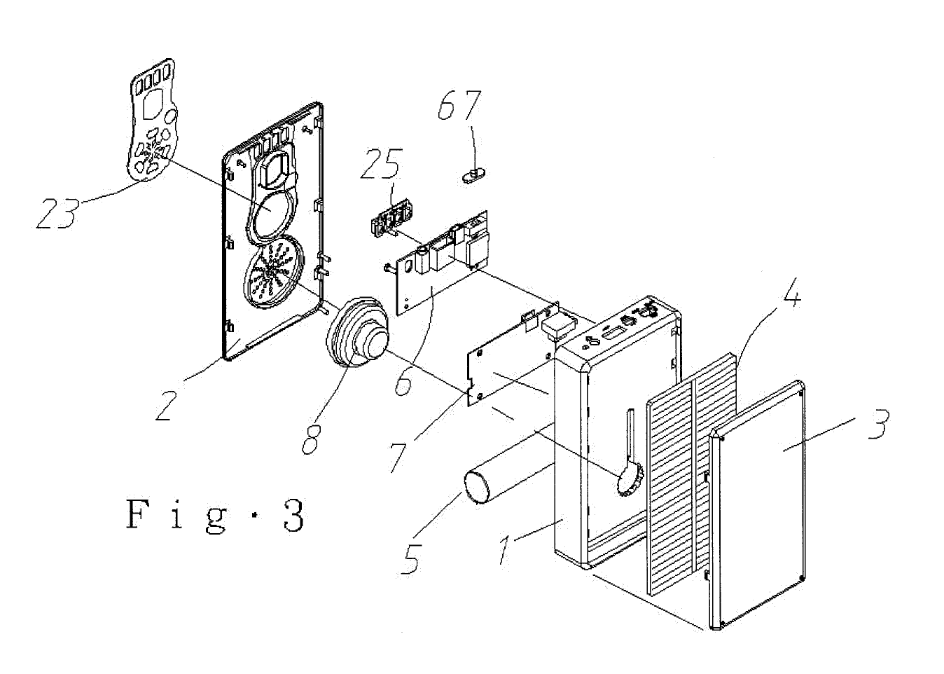

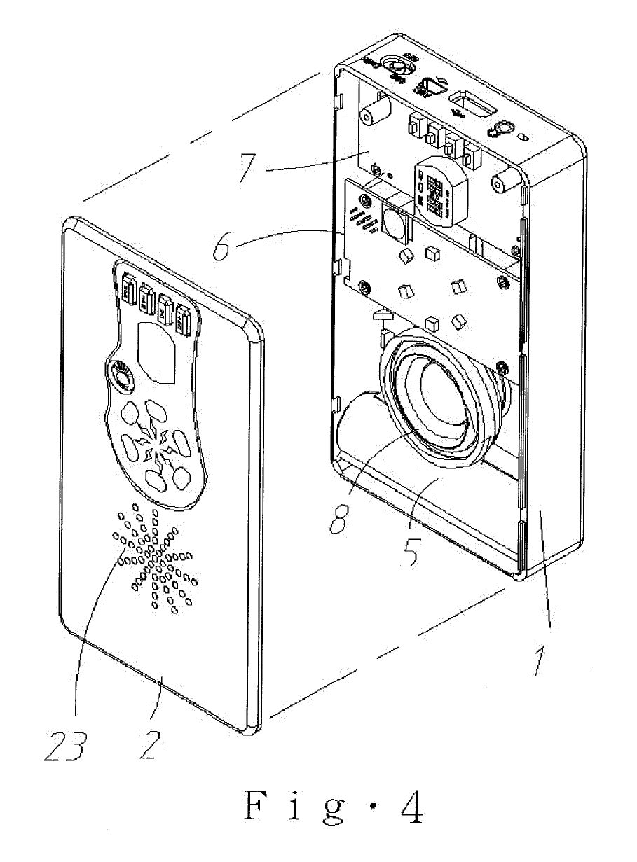

Referring to FIG. 1 through FIG. 4, according to the present invention, a mini solar portable multi-device has a body 1. The body 1 includes a front cover 2 and a back cover 3. The body 1 may be sized as 136 mm×75 mm×30 mm. The back cover 3 covers a (monocrystalline silicon) solar module 4 (as shown in FIG. 3) that convers solar energy into electric energy and sends the electric energy to a battery 5 inside the body 1 for supplying power. The body 1 further contains a partition 10 that has a front surface installed with a radio control circuit board 6 and a light-emitting member control circuit board 7 thereon (by screwing as shown). The light-emitting member control circuit board 7 is equipped with a ring-like (not limited thereto, alternatively being square or array-like) light-emitting member 70 and a light-emitting control circuit (not shown) as well as a brightness and light-emitting mode touch switch 71 and a light-detection control circuit (not shown in the drawings and on and off in response to the operation of the witch 71). The light-emitting member 70 comprises a plurality of light-emitting diodes for providing constant illumination or warning flashes, wherein the number of the light-emitting diodes may be six as shown in the drawing, but is not limited thereto, and may be of cool white. The radio control circuit board 6 is provided with a set of connectors, which includes a USB connector 61 and a mini USB connector 62. Also provided on the radio control circuit board 6 are an earphone jack 63 and an audio changeover switch 64 that is protected by a sheath 67. At the lower part of the body 1, there are a battery compartment 11 that receives a battery 5, which is preferably a lithium-ion battery in the present invention, and a loudspeaker seat 12 that holds a loudspeaker 8, which sounds audio signals or acoustic warnings. The device thus can perform self-charging when exposed in sunlight and then charge an external cell phone through a charger connector 60 that is deposited at a lateral of the body 1 and communicated with the radio control circuit board 6. The front cover 2 is provided with a button set 20 that is communicated with the radio control circuit board. The button set 20 is covered by plastic protective covering 25 while passing through holes formed on the front cover 2 to be exposed at holes formed on a pervious-to-light plate 23. The button set 20 (including four buttons as shown) comprises a button for selecting playing modes (the first from the left), two buttons for selecting tracks and for adjusting he volume (the second from the left for upward adjustment and the first from the right for downward adjustment), and a button for selecting radio stations (the second from the right). The front cover 2 is equipped with a display screen 21 for displaying the power level, the playing mode and the number of tracks. The front cover 2 has a light-penetrable area 22 (embodied by the transparent pervious-to-light plate 23 and located corresponding to the light-emitting member 70) and a sound-penetrable area 24 (realized by a matrix-like hole array and located corresponding to the loudspeaker 8). The body 1 has a lateral provided with a power-level indicating lamp 65 and a micro SD card connector 66.

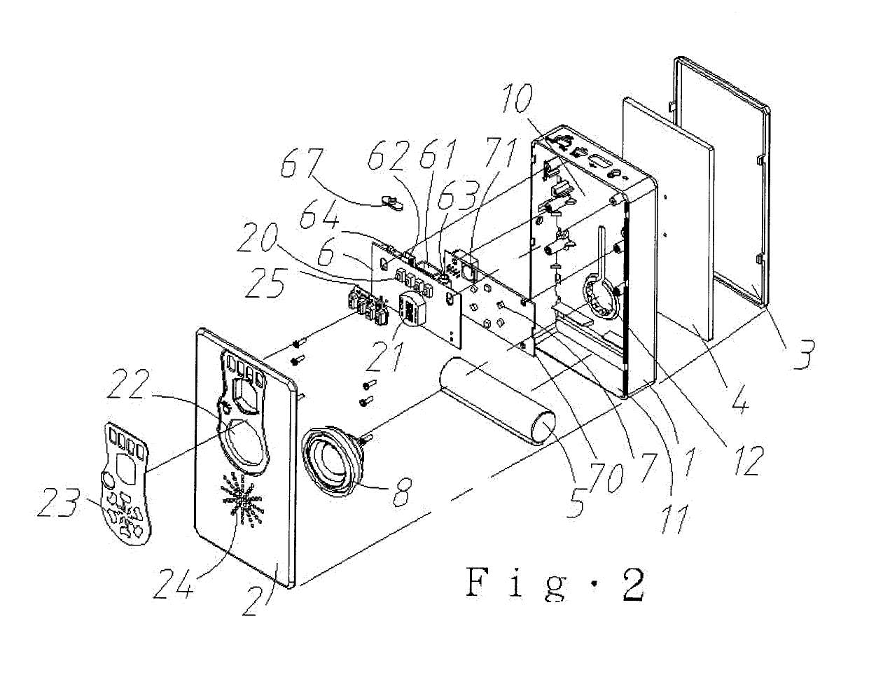

The disclosed device operates in a full-power pure light control. When there is no sunlight or the ambient illumination is lower than a preset threshold, the power-level indicating lamp 65 (yellow) associated with solar charging puts out, as shown in FIG. 1, and the controller delays for 3-5 seconds (depending on the intensity of the illumination) to trigger the power output signal, so that the power output is activated and the LEDs light up. When there is sunlight or the ambient illumination is higher than the preset threshold, the power-level indicating lamp 65 (yellow) associated with solar charging lights up as shown in FIG. 1, and the controller delays for 3-5 seconds (depending on the intensity of the illumination) to terminate the power output signal, so that the power output is deactivated and the LEDs put out. It is possible to manually turn on the LEDs of the light-emitting member 70 by pressing and holding the switch 71 for 1-3 seconds. At this time, the LEDs provide 100% of their illumination. When a second touch is applied to the switch 71, the illumination of the LEDs is dimmed to 80%, and a third touch dims the illumination to 50%, while a fourth touch dims the illumination to 30%. A fifth touch enters the LEDs into a flashing mode. By pressing and holding the switch 71 for 1-3 seconds once again, the light-emitting member 70 is turned off. The switch 71 is located as shown in FIG. 2.

Referring to FIG. 1, the power-level indicating lamp 65 remains dark during the sole performance of the radio function, and only lights up in red or green when the lighting switch 71 is on or when the device charges an external cell phone at 5V-800 mAh to indicate the battery power level. When the solar module 4 gets charged by sunlight, the yellow LED of the power-level indicating lamp 65 associated to the battery 5 lights up, indicating that the battery 5 is charged by the solar energy, and automatically puts out when the battery 5 is fully charged.

The disclosed device may support for example micro SD (SanDisk) cards, TF (Trans-flash) cards, USB connection and AUX for playing music of the MP3 format (for TF cards and USB, up to the capacity of 32 G). The audio changeover switch 64 switches the device between the radio function and the SOS function. When the switch 64 is put to a Radio Position associated to the radio function, the device automatically detects whether there is a USB stick or a TF card connected and containing any MP3 files to be displayed. If so, the device stays at the USB or Card mode (as seen from the display screen 21 through the pervious-to-light plate 23), and directly plays the MP3 files. If there is no readable medium in the USB or TF socket, the device automatically operates in the Radio Mode. The device has a resumption function that continues playing of a radio station /MP3 file at the point it is stopped in the previous operation, so as to eliminate the need of resetting the radio station or the situation of playing the MP3 file from its beginning. When the switch 64 is in the Radio Mode and the display screen displays so, by pressing and holding the button for selecting the playing modes (Play/Pause/Scan) for more than 1 second, the device starts to scan and store available radio stations automatically, and the number stops growing when the scanning is over, at which time the automatic scanning process is done. Normally, the radio broadcast content of one of the scanned stations will be automatically played right after the scanning. If the device does not do so, the button for switching tracks or adjusting volume (Next/Vol+) has to be pressed and held for more than 1 second to build up the volume so as to make sure the silence is not because the volume level is too small to make the content be heard.

The button for mode selection is used to switch between four modes: Card, Radio FM, USB and AUX. The button for switching tracks or adjusting volume (PREV/Vol−) mainly serves to allow the selection of the previous track/radio station, and when pressed and held for more than 1 second, can reduce the volume. The button playing and pausing music and switching between radio stations (Play/Pause/Scan) allows the selection of tracks/radio stations and the activation of playing and pausing, and when pressed and held for more than 1 second, can activate automatic scanning and storing of FM radio stations. The other button for switching tracks or adjusting volume (Next/Vol+) buttons mainly serves to allow the selection of the next track/radio station, and when pressed and held for more than 1 second, can increase the volume.

The disclosed device also serves to indicate the voltage of the battery. When the battery voltage is more than 3.4V, the lamp related to the full power level lights up. When the battery voltage is 3.4V or lower, the lamp related to the full power level goes out and the lamp related to the low power level flashes. When the battery voltage is lower than 3.2V, the radio function and the SOS alarm function are automatically turned off. On the other hand, when the device is charged by an external 5V power source, a red USB Charging lamp lights up, indicating that the battery is charged by an external power source, and the lamp automatically dies out when the battery is fully charged. With the battery fully charged (having a capacity of 4.2V), the illumination function can continuously run for more than 10 hours. With the battery fully charged (having a capacity of 4.2V), the radio function can continuously run for more than 10 hours. It is preferred that when the battery is charged, the illumination function is deactivated so as to prevent the device from automatically turning on the illumination function and consuming power. In cloudy days, it is possible to use an external power source of 5V-500-1000 mAh to charge the battery 5 through the USB connector 61 or the mini USB connector 62.

With the configuration as described above, the present invention implements a comprehensive concept of unique design to integrate regular illumination, emergency illumination, warning and radio as an integral device, which uses solar energy as its power source. The power generated from solar energy can not only supply for its own need but also be used to charge an external cell phone. The device in normal days provides music and broadcast contents, and in emergency provides illumination and acoustic warnings, thus being convenient and useful for improving users' safety. Since the disclosed device is easy to be understand and implement, and provides outstanding usability and convenience, it is totally different from the conventional devices.

The present invention has been described with reference to the preferred embodiments and it is understood that the embodiments are not intended to limit the scope of the present invention. Moreover, as the contents disclosed herein should be readily understood and can be implemented by a person skilled in the art, all equivalent changes or modifications which do not depart from the concept of the present invention should be encompassed by the appended claims.

What is claimed is:

1. A mini solar portable multi-device, comprising a body that includes a front cover and a back cover, the back cover covering a solar module, which converts solar energy into electric energy and transmits the electric energy to a battery in a battery compartment inside the body for supplying power; the body containing a partition on which a radio control circuit board and a light-emitting member control circuit board are deposited adjacently, the light-emitting member control circuit board being provided with a light-emitting member, a light-emitting control circuit, a brightness and light-emitting mode touch switch, and a light-detection control circuit for providing consistent illumination or warning flashes, the radio control circuit board being equipped with a connector set and an audio changeover switch, a loudspeaker seat deposited in a lower part of the body for holding a loudspeaker that sounds audio signals or acoustic warnings, the devices being able to perform self-charging when exposed in sunlight or otherwise get charged by the grid, and then charge an external cell phone through a charger connector that is located on a lateral of the body and communicated with the radio control circuit board; the front cover comprising a button set that is communicated with the radio control circuit board, wherein the button set includes buttons for selecting playing modes, for switching tracks or adjusting volume, for playing or stopping, and for playing and pausing music and switching between radio stations, respectively; and the front cover having a light-penetrable area and a sound-penetrable area.

2. The mini solar portable multi-device of claim 1, wherein the solar module is a monocrystalline silicon solar module.

3. The mini solar portable multi-device of claim 1, wherein the light-emitting member comprises a plurality of light-emitting diodes.

4. The mini solar portable multi-device of claim 1, wherein the light-emitting member has a ring-like shape.

5. The mini solar portable multi-device of claim 1, wherein the connector on the radio control circuit board comprises a USB connector and a mini USB connector and an earphone jack.

6. The mini solar portable multi-device of claim 1, wherein the front cover is provided with a display screen for displaying power level, playing mode, number of tracks.

7. The mini solar portable multi-device of claim 1, wherein the body has the lateral further provided with a power-level indicating lamp and a micro SD card connector.
